(19) United States
(12) Patent Application Publication
(10) Pub. No.: US 2008/0020324 A1
(43) Pub. Date: Jan. 24, 2008

(54) IMMERSION LITHOGRAPHY DEFECT REDUCTION WITH TOP COATER REMOVAL

(75) Inventors: Lin-Hung SHIU, Hsinchu City (TW); Fu-Jye LIANG, Kaohsiung City (TW); Chun-Kuang CHEN, Hsin-Chu Hsien (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/458,621

(22) Filed: Jul. 19, 2006

(51) Int. Cl. G03F 7/26

(52) U.S. Cl. 430/311; 430/330

(57) ABSTRACT

A method for photolithography processing includes providing a substrate coated with a photosensitive layer thereon and a top coater overlying the photosensitive layer; exposing the photosensitive layer to a radiation energy; removing the top coater; and baking the photosensitive layer after the removing of the top coater layer.

### BACKGROUND

As semiconductor fabrication technologies are continually progressing to smaller feature sizes such as 65 nanometers, 45 nanometers, and below, immersion lithography methods are being adopted. Immersion lithography involves immersing a substrate, or at least a part of an immersion lithography system, in an immersion fluid.

Immersion lithography often uses a new type of photoresist material, referred to as chemical amplified resists (CAR), along with shorter wavelength light such as deep ultraviolet (DUV) including 248 nm UV by krypton fluoride (KrF) excimer lasers and 193 nm UV by argon fluoride (ArF) excimer lasers. The shorter wavelength light is used to expose the CAR to create patterns on the substrate of exposed and unexposed regions of resist. In CAR, photo generated acid (PGA) in exposed regions often diffuses into unexposed regions through an immersion fluid, causing blurring and resulting in lateral bias of the exposed image. A top coater is applied onto the photoresist to protect the photoresist layer from the above leaching effect. However, defects often result. For example, the top coater sometimes traps the immersion fluid (e.g. water) due to water penetration and introduces other defects such as water stains.

What is needed is an improved system and method for performing lithography, such as immersion lithography, with a reduced amount of defects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of one embodiment of a method of lithography patterning constructed according to aspects of the present disclosure.

FIGS. 2 through 7 illustrate sectional views of one exemplary semiconductor device utilizing the method of FIG. 1 constructed according to aspects of the present disclosure.

### DETAILED DESCRIPTION

It is understood that the following disclosure provides many different embodiments, or examples, capable of implementing different features of the invention. Specific examples of components and arrangements are described below to simplify and thus clarify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed interposing the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

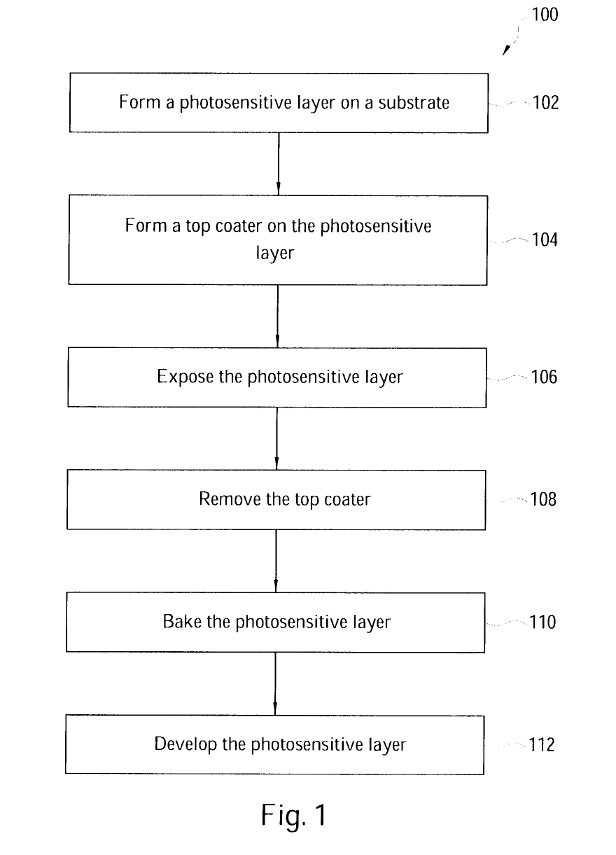

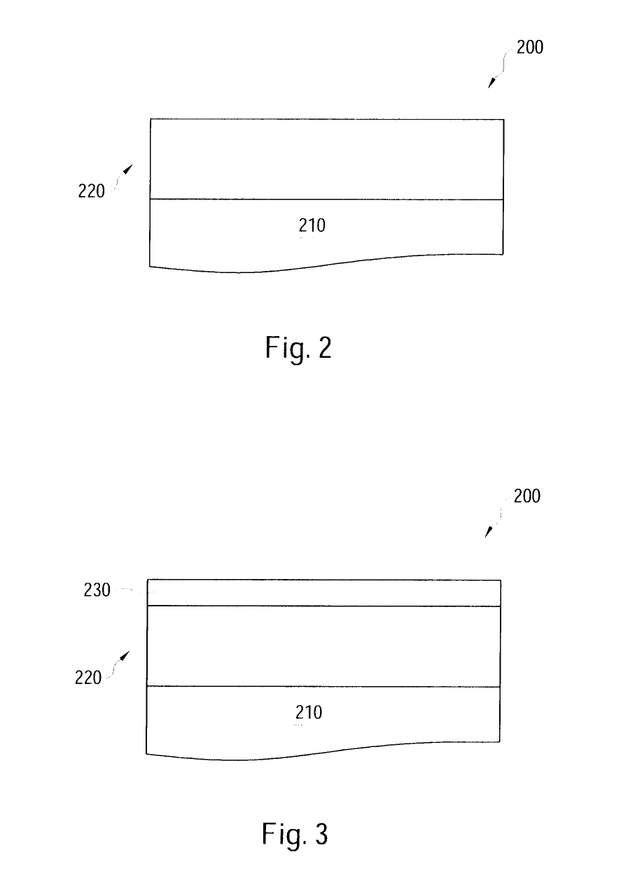

FIG. 1 is a flowchart of one embodiment of a method 100 of lithography patterning constructed according to aspects of the present disclosure. FIGS. 2 through 7 illustrate sectional views of one exemplary semiconductor device 200 utilizing the method 100 during various fabrication stages. With reference to FIGS. 1 through 7, the method 100 and the exemplary semiconductor device 200 fabricated thereby will be collectively described below.

Referring to FIG. 1 and FIG. 2, the method 100 is initiated at step 102 by forming, on a substrate 210 of the semiconductor device 200, a resist layer (photosensitive layer or photoresist layer) 220. The semiconductor device 200 may be a semiconductor wafer or other suitable device. In the present embodiment, the substrate 210 includes silicon. The substrate may alternatively include other suitable semiconductor material, including Ge, SiGe, or GaAs. The substrate 210 may further include other materials such as low k dielectric material, silicon oxide, and conductive material. The substrate 210 may have other structures such as doped regions including wells and source/drain; isolations features including shallow trench isolation (STI) and inter-level dielectric (ILD); conductive features including gate electrodes, metal lines, vias, and contacts. The substrate 210 may alternatively include a non-semiconductor material such as a glass plate for thin-film-transistor liquid crystal display (TFT-LCD) devices or a fused quartz plate for photomasks. The substrate 210 may further include one or more material layers to be patterned. For example, the material layer(s) to be patterned may include a silicon layer, a dielectric layer, or a doped poly-silicon layer.

Additionally, the substrate 210 may include a bottom anti-reflecting coating (BARC) layer formed on the material layer(s) to be patterned. The BARC layer is designed to have a proper refractive index and/or a thickness to reduce light reflection during a lithography process and enhance lithography patterning performance. The BARC layer may include an organic material, a nitride material, or an oxide material, and may have a thickness ranging between about 100 angstrom and 1000 angstrom.

A resist layer 220 is formed on the substrate 210. For example, the resist layer 220 may be formed on the BARC layer disposed on the substrate 210. The resist layer 220 may have a thickness ranging between about 50 angstroms and 5000 angstroms. In another embodiment, the resist layer 220 may have a thickness ranging between about 500 angstroms and 2000 angstroms. The formation of the resist layer 220 may be implemented by a technique such as spin-on coating. Additionally, a bake process may be applied to the resist layer 220 to reduce solvent in the resist layer, referred to as a soft baking process.

In the present embodiment, the resist layer is a chemical amplifier resist (CAR). The resist layer 220 includes a polymer material that turns soluble to a developer such as a base solution when the polymer is reacted with acid. Alternatively, the resist layer 220 includes a polymer material that turns insoluble to a developer such as a base solution when the polymer is reacted with acid. The resist layer 220 further includes a solvent filling inside the polymer. The solvent may be partially evaporated due to a prior baking process (such as a soft baking process). The resist layer 220 also includes a photoacid generator (PAG). When absorbing photo energy (or radiation energy), the PAG decomposes and forms a small amount of acid.

Referring to FIG. 1 and FIG. 3, the method 100 proceeds to step 104 by forming a top coater 230 on the resist layer 220. The top coater 230 may be disposed directly on the resist layer 220. The top coater 230 may have a thickness ranging between about 50 angstrom and about 10000 angstrom. The top coater 230 is formed by a technique such as spin-on coating or other suitable methods. The top coater 230 is hydrophobic to an immersion fluid (e.g., water) employed in an immersion lithography process. For example, the top coater 230 may be tuned to have a contact angle larger than about 50 degree. The top coater 230 may include organic materials and/or polymer materials. In one example, the top coater 230 includes a fluoride-containing material such as a fluoride compound having fluoride content ranging from about 0.5% to about 30% in weight. In another embodiment, the top coater 230 may have a multiple-layer structure disposed on the resist layer 220.

A top anti-reflective coating (TAR) layer may be additionally formed on the resist layer 220 either over the top coater 230 or interposed between the resist layer 220 and the top coater 230. The TAR layer may be formed by a spin-on coating technique. Alternatively, the TAR may be combined with the top coater 230 such that the top coater 230 can also serve for antireflection during a lithography exposing process.

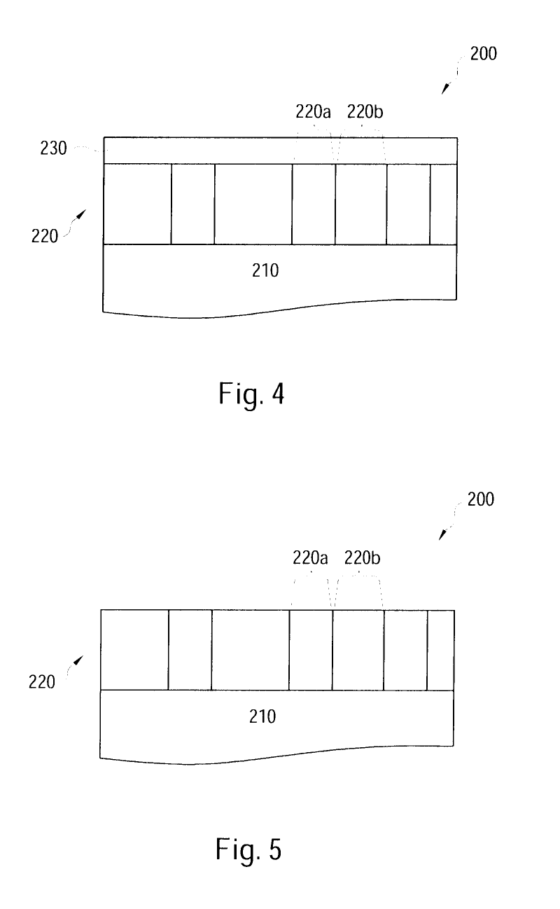

Referring to FIG. 1 and FIG. 4, the method 100 proceeds to step 106 by exposing the resist layer 220 to photo energy. During a photolithographic patterning process, the resist layer 220 is exposed to a radiation energy such as deep ultra-violet (DUV) through a photomask (also referred to as a mask or reticle) having a predefined pattern, resulting in a resist pattern that includes a plurality of exposed regions such as exposed features 220a and a plurality of unexposed regions such as unexposed features 220b. The mask may include a transparent substrate and a patterned absorption layer. The transparent substrate of the mask may use fused silica (SiO2) such as borosilicate glass and soda-lime glass. The transparent substrate of the mask may use calcium fluoride and/or other suitable materials. The patterned absorption layer may be formed using a plurality of processes and a plurality of materials, such as depositing a metal film made with chromium (Cr) and iron oxide, or an inorganic film made with MoSi, ZrSiO, SiN, and/or TiN. The radiation energy may include a 193 nm beam by Argon Fluoride (ArF) excimer lasers, or a 157 nm beam by Fluoride (F2) excimer lasers. The exposed PAG in the resist layer 220 is decomposed as anion and acid, resulting in the resist being more soluble to water than unexposed resist. The exposing process may be implemented by a lithography tool such as a scanner, a stepper, or a cluster tool capable of photon exposure processing.

The exposing process may be performed utilizing an immersion lithography technique wherein an immersion fluid is disposed between the lens of the lithography tool and the semiconductor device 200 during an exposing process. For example, de-ionized water (DI water or DIW) may be used as an immersion fluid for exposing processes. Since the resist layer 220 is protected and separated by the top coater 230 from the immersion fluid, PAG diffusion issues are substantially eliminated.

The lithography apparatus to implement an immersion exposing process is described below as an example. The lithography apparatus includes a substrate stage designed to secure a substrate to be processed. The substrate stage is operable to move the substrate relative to the apparatus. For example, the substrate stage is capable of translational and/or rotational displacement for substrate alignment, stepping, and scanning. The substrate stage may include various components suitable to perform precise movement. The lithography apparatus includes one or more imaging lens systems (referred to as a “lens system”). A substrate such as the semiconductor device 200 may be positioned on the substrate stage under the lens system. Each lens element thereof may include a transparent substrate and may further include a plurality of coating layers. The transparent substrate may be a conventional objective lens, and may be made of fused silica (SiO2), calcium-fluoride (CaF2), lithium fluoride (LiF), barium fluoride (BaF2), or other suitable material. The materials used for each lens element may be chosen based on the wavelength of light used in the lithography process to minimize absorption and scattering. The apparatus may include an immersion fluid retaining module designed for holding an immersion fluid and/or other proper fluid such as a cleaning fluid. The immersion fluid retaining module may be positioned proximate (such as around) the lens system and designed for other functions, in addition to holding the immersion fluid. The immersion fluid retaining module may include various apertures (or nozzles) for providing an immersion fluid for an exposure process, and/or performing other proper functions. The lithography apparatus may further include a radiation source. The radiation source may be a suitable ultraviolet (UV) or extra UV(EUV) light source. For example, the radiation source may be a mercury lamp having a wavelength of 436 nm (G-line) or 365 nm (I-line); a Krypton Fluoride (KrF) excimer laser with wavelength of 248 nm; an Argon Fluoride (ArF) excimer laser with a wavelength of 193 nm; a Fluoride (F2) excimer laser with a wavelength of 157 nm; or other light sources having a desired wavelength (e.g., below approximately 100 nm). The apparatus may include a chamber to provide a vacuum environment or a low pressure environment with inert gas for protecting various components and a substrate to be processed. An example of an immersion lithography system is provided in U.S. Ser. No. 60/729,565, filed Oct. 24, 2005, which is hereby incorporated by reference.

Referring to FIGS. 1 and 5, the method 100 proceeds to step 108 by removing the top coater after the exposing process at step 106. The top coater 230 may be removed by a proper solution capable of dissolving the top coater material. In one embodiment, a developer solution for developing a resist layer may also be utilized for removing the top coater 230. Since the resist layer 220 is not yet post-baked, it is not dissolvable at this stage. Therefore, the top coater layer 230 can be selectively removed. In another embodiment, a water-based solvent can be implemented to remove the top coater 230. The water-based solvent may contain surfactant. Step 108 may additionally include a cleaning process such as a water rinsing or other suitable cleaning processes after the removal of the top coater 230.

Alternatively, the top coater 230 may be partially removed. In one example, the top coater 230 may be thinned using a technique similar to that used for removal of the top coater with a controlled period of time. Thus the thickness of the top coater is substantially reduced and the top coater associated defects are also substantially reduced or eliminated. In another example, the top coater 230 includes two layers, a first layer (overlying a second layer) is properly removed by a method capable of selectively remove the first layer from the second layer to eliminate the top coater related defects. When the top coater 230 is removed after the exposing process, the top coater related issues such as water penetration and stains can be substantially eliminated or reduced.

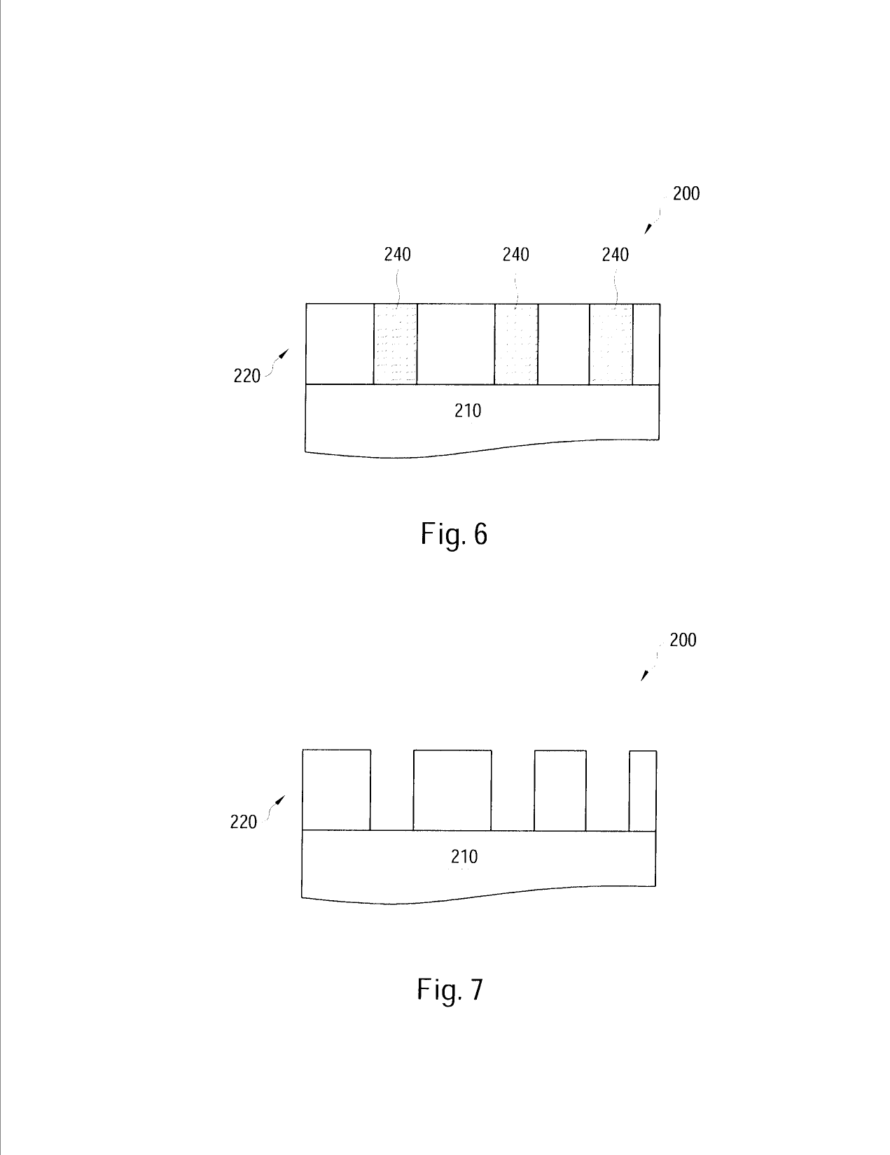

Referring to FIGS. 1 and 6, the method 100 proceeds to step 110 by baking the resist layer 220 after the removal of the top coater at step 108, referred to as a post exposure baking (PEB) process. During the PEB process, the photo generated acid induces a cascade of chemical transformations in the resist layer 220, referred to as chemical amplification. The transformations turn the exposed regions of the resist layer 220 (such as exposed regions 220a) into resist features 240 soluble to the developer. The PEB process may have a temperature (or a temperature profile as a function of time) and a baking duration defined and controlled for optimized resist patterning.

Referring to FIGS. 1 and 7, the method 100 then proceeds to step 112 to develop the resist layer 220 utilizing a developer. The resist layer in the exposed regions are substantially dissolved, resulting in a patterned resist layer 220 having one or more openings and exposed substrate 210 within the openings. In one embodiment, the developer may be a tetramethylammonium hydroxide (TMAH) based solution. Since the top coater 230 is removed before the PEB process at step 110, the top coater related issues including water penetration and other defects are substantially eliminated.

The method 100 may further include other processing steps after the developing of resist layer 220 at step 112, such as baking, etching/implanting, and/or stripping the resist layer. For example, after an etching process applied to an underlying material layer within the openings of the patterned resist layer and a recessing pattern is formed thereby in the substrate, the resist layer may be removed thereafter by a wet stripping, plasma ashing, or a combination thereof. The present disclosure may have various variations. In one example, the disclosed method is not limited to patterning a semiconductor substrate. Other substrate such as a glass substrate for TFT_LCD devices, or a transparent substrate (such as fused quartz) for photomask may be patterned using the disclosed material, method, and apparatus. In another variation, the exposing process at step 106 may be implemented by an immersion lithography process utilizing another immersion fluid than water. For example, a solution with water and proper additives may be used for immersion lithography processing.

Thus, the present disclosure provides a method for photolithography processing. The method includes providing a substrate coated with a photosensitive layer thereon and a top coater overlying the photosensitive layer; exposing the photosensitive layer to a radiation energy; removing the top coater; and baking the photosensitive layer after the removing of the top coater layer.

The disclosed method may further include developing the exposed photosensitive layer after the baking of the photosensitive layer. The removing of the top coater may include utilizing a developing solution to remove the top coater. The removing of the top coater may include utilizing a water-based solvent containing surfactant to remove the top coater. The photosensitive layer may include chemical amplification resist (CAR). The top coater may include an organic material. The top coater may include a hydrophobic material. The top coater may include a hydrophobic material having a contacting angle greater than about 50 degree for water. The top coater may include a fluorine-containing material. The fluorine-containing material may include fluorine content ranging between about 0.5% and about 30% in weight. The top coater may include a thickness ranging between about 50 angstrom and about 10000 angstrom. The method may further include a cleaning process applied to the photosensitive layer after the removing of the top coater. The cleaning process may utilize de-ionized water (DIW). The exposing of the photo sensitive layer may include performing the exposing in an immersion lithography environment. The substrate may be selected from the group consisting of a semiconductor substrate, a photomask substrate, and thin-film-transistor liquid-crystal-display (TFT-LCD) substrate.

The present disclosure also provides another method for photolithography patterning. The method includes forming a photosensitive layer on a substrate; forming a top coater on the photosensitive layer; exposing the photosensitive layer to a radiation energy; at least partially removing the top coater; baking the photosensitive layer after the removing of the top coater layer; and developing the exposed photosensitive layer.

In the disclosed method, the top coater may be removed by utilizing a solution to reduce a thickness of the top coater. The solution may be selected from the group consisting of a developing solution and a water-based solution. The forming of the top coater may include forming a hydrophobic material disposed on the photosensitive layer.

The present disclosure also provides another method for photolithography patterning. The method includes forming a photoresist layer on a semiconductor substrate; forming a hydrophobic top coater on the photosensitive layer; exposing the photosensitive layer to a radiation energy in an immersion lithography mode; removing the top coater; thereafter baking the photosensitive layer; and developing the photosensitive layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method for photolithography processing, comprising:
providing a substrate coated with a photosensitive layer thereon and a top coater overlying the photosensitive layer;
exposing the photosensitive layer to a radiation energy;
removing the top coater; and
baking the photosensitive layer after the removing of the top coater layer.

2. The method of claim 1, further comprising developing the exposed photosensitive layer after the baking of the photosensitive layer.

3. The method of claim 1, wherein the removing of the top coater comprises utilizing a developing solution to remove the top coater.

4. The method of claim 1, wherein the removing of the top coater comprises utilizing a water-based solvent containing surfactant to remove the top coater.

5. The method of claim 1, wherein the photosensitive layer comprises chemical amplification resist (CAR).

6. The method of claim 1, wherein the top coater comprises an organic material.

7. The method of claim 1, wherein the top coater comprises a hydrophobic material.

8. The method of claim 7, wherein the top coater comprises a hydrophobic material having a contacting angle greater than about 50 degree for water.

9. The method of claim 1, wherein the top coater comprises a fluorine-containing material.

10. The method of claim 9, wherein the fluorine-containing material comprises fluorine content ranging between about 0.5% and about 30% in weight.

11. The method of claim 1, wherein the top coater comprises a thickness ranging between about 50 angstrom and about 10000 angstrom.

12. The method of claim 1, further comprising a cleaning process applied to the photosensitive layer after the removing of the top coater.

13. The method of claim 12, wherein the cleaning process utilizes de-ionized water.

14. The method of claim 1, wherein the exposing of the photo sensitive layer comprises performing the exposing in an immersion lithography environment.

15. The method of claim 1, wherein the substrate is selected from the group consisting of a semiconductor substrate, a photomask substrate, and thin-film-transistor liquid-crystal-display (TFT-LCD) substrate.

16. A method for photolithography patterning, sequentially comprising:
forming a photosensitive layer on a substrate;
forming a top coater on the photosensitive layer;
exposing the photosensitive layer to a radiation energy;
at least partially removing the top coater;
baking the photosensitive layer after the removing of the top coater layer; and
developing the exposed photosensitive layer.

17. The method of claim 16, wherein the at least partially removing of the top coater comprises reducing a thickness of the top coater utilizing a solution.

18. The method of claim 17, wherein the solution is selected from the group consisting of a developing solution and a water-based solution.

19. The method of claim 16, wherein the forming of the top coater comprises forming a hydrophobic material disposed on the photosensitive layer.

20. A method for photolithography patterning, comprising:
forming a photoresist layer on a semiconductor substrate;
forming a hydrophobic top coater on the photosensitive layer;
exposing the photosensitive layer to a radiation energy in an immersion lithography mode;
removing the hydrophobic top coater;
baking the photosensitive layer after the hydrophobic top coater has been removed; and
developing the baked photosensitive layer.
